(19) United States
(12) Patent Application Publication
(10) Pub. No.: US 2019/0386474 A1
(43) Pub. Date: Dec. 19, 2019

(54) METHOD FOR PRINTED CABLE INSTALLATION IN HARNESS SYSTEMS FOR AIRCRAFTS

(71) Applicants: AIRBUS OPERATIONS (S.A.S.), Toulouse (FR); AIRBUS OPERATIONS S.L., Madrid (ES); AIRBUS OPERATIONS GMBH, Hamburg (DE)

(72) Inventors: Alain RODEGHIERO, Pibrac (FR); Jose SANCHEZ-GOMEZ, Madrid (ES); Tamara BLANCO VARELA, Madrid (ES); Cristobal Federico BRITO MAUR, Breman (DE)

(21) Appl. No.: 16/440,165

(22) Filed: Jun. 13, 2019

(30) Foreign Application Priority Data
Jun. 13, 2018 (EP) 18382418-4

(51) Int. Cl. H02G 3/30; H05K 3/12; H05K 3/10; H05K 1/09; H02G 1/06; B64D 47/00; B64C 1/14

(52) U.S. Cl. CPC H02G 3/30; H05K 3/1283; H05K 3/125; H05K 3/102; H05K 1/09; B64D 2221/00; H02G 1/06; B64D 47/00; B64C 1/1407; H05K 2203/107; H05K 2203/1131; H05K 3/1208

(57) ABSTRACT

A method for printed cable installation in a harness system of an aircraft. The method includes: printing at least a first conductive trace comprising conductive particles to a surface of an aircraft with a printing technology; printing at least second conductive trace comprising conductive particles to the surface of an aircraft with the printing technology; sintering the first and the second conductive traces by a laser, and interposing an insulating film between the first and the second conductive traces. For a trace length less than 5 meters, the first and second conductive traces provide the electromagnetic compatibility of a twisted pair of wires when printed with a guard trace.

### RELATED APPLICATION

This application claims priority to European Patent Application 18382418-4 filed Jun. 13, 2018, the entirety of which is incorporated by reference.

### FIELD OF THE INVENTION

The present invention relates to a method for cable installation that prints conductive traces onto a surface of a component in an aircraft. The conductive traces are included in the electrical circuit of a harness system for the component. The conductive traces are printed on the surface of a composite element, such as a housing for the component.

### BACKGROUND OF INVENTION

Traditionally, electrical cables are routed throughout an aircraft and in particularly through the aircraft fuselage using cable routing harnesses which are substantially inflexible structural members for assembly of cables, such as coaxial cables and twisted pair cables. A harness system typically includes many cables and several individual harnesses. Installing a harness system in an aircraft is a costly and labor-intensive process that often requires drilling of parts and installation of screws to secure the harnesses to the aircraft. The current installation processes for harness systems can be very time consuming, especially when dealing with complex locations, e.g. a harness system for a door of an aircraft. Harness systems for aircraft doors can require 24 cables to be assembled on the door of the aircraft as shown in FIG. 1.

Currently, every harness cable installation must go through a support installation process that involves part drilling, screwing, and/or adhesion steps before the cables are installed and connections are made to the installed cables, as shown in FIG. 2. Harness cable installation can be a costly procedure with a requirement of an accurate process control to avoid compromising the system quality and performance. Furthermore, conventional cable installation procedures increase lead time, material costs and imply human-sourced defects.

### SUMMARY OF INVENTION

A method for cable installation in harness systems that simplifies the current cable installation methods and solves the aforementioned drawbacks has been invented and is disclosed herein.

The method for cable installation in harness systems for aircraft may be embodied as a simplified current harness cable installation method that reduces the conventional support installation processes needed in prior cable installation and cable connections processes.

In one aspect, the present invention refers to a method for cable installation in harness system that comprises printing pairs of independent conductive traces on a component surface or fuselage structure of an aircraft. The independent pairs of conductive traces are electromagnetically compatible if printed with a guard trace to reduce cross-talk between the traces. The pairs of conductive traces are functionally equivalent to conventional twisted wire pairs for a trace length less than five (5) meters. The guard traces may be grounded at one or both of their ends.

In an embodiment, a composite element for an aircraft with an integrated harness system is manufactured. The harness system is formed by printing a predetermined number of pairs of conductive traces on a surface of the composite element with an additive printing technology configured to print electronics. The additive printing technology permits applying metallic printed paths (traces) on composite element of the aircraft. Printed technologies for electronics can create electrical devices on various substrates (surfaces) using low cost processes. Examples of additive printing technologies used according to the present invention are ink-based technologies, e.g. ink-jet printing as aerosol jet and powder-based technology, e.g. gas dynamic cold spray (CS). Copper, as well as other conductors, fit well the electrical capabilities of the printed cables with a maximum linear resistance of 340/km.

The aforementioned additive printing technologies provide adhesion stability to avoid the peel off of the metallic printed paths. Furthermore, the applied printed paths achieve the correct thickness to support the electrical requirements of the system, mainly, current and linear electrical resistance.

In one example according to the present disclosure, the harness system is a system for a door of an aircraft and wherein the metallic printed paths are printed on the Carbon Fiber Reinforced Polymer Frame (hereinafter CFRP) door surface based on any of the aforementioned additive printing techniques.

By printing pairs of conductive traces to replace conventional wire cables, the installation of cables in an aircraft is simplified by reducing the number of cables to be installed and resulting in cost and labor savings during the installation process. Furthermore, the method may be automated in that additive printers may be programmed to print pairs of conductive traces on a surface of an aircraft component. Automating the printing of conductive traces reduces the manual steps and risk of defects due to manual installation of a cable harness system.

Furthermore, the inventive method may reduce the time, cost and resources needed for cable harness installation in an aircraft or in a component for an aircraft. Additionally, electronic printing allows a reduction of the installation duration; thus, a reduced lead time is possible and related resources are saved. Since the conductive traces or metallic paths are automatically printed, a multifunctional modularization is possible, so consequently the assembly efforts can be reduced. Furthermore, the amount of solid parts compared to conventional systems is decreased with a corresponding weight reduction, and therefore the available space increases.

The invention may be embodied as a method to install conductive elements on a component for an aircraft, the method comprising: identifying a surface of the component suitable for receiving printed conductive material, wherein the surface of a Carbon Fiber Reinforced Polymer Frame (CFRP); mapping a first path for conductive traces, wherein the first path is less than five (5) meters and at least 0.5 meters; printing first and second conductive traces along the first path, wherein the printing includes printing conductive particles onto the surface along the first path, wherein a gap between the first and second conductive traces is no greater than 10 millimeters along the lengths of the conductive traces; sintering the first and the second conductive traces by heating the first and second conductive traces with a laser; placing a first insulating film or trace between the first and the second conductive traces and along the lengths of the first and second conductive traces; connecting each of the first and second conductive traces to a first connector for a first electrical component of the aircraft, and grounding the first insulating film or trace.

The method may further comprise: mapping a second path for conductive traces, wherein the second path is less than five (5) meters and at least 0.5 meters, wherein the second path is separated by at least five (5) meters from the first path; printing third and fourth conductive traces along the second path, wherein the printing includes printing conductive particles onto the surface along the first path, wherein a gap between the first and second conductive traces is no greater than 10 millimeters along the lengths of the conductive traces; sintering the third and the fourth conductive traces by heating the third and fourth conductive traces with the laser; placing a second insulating film or trace between the third and the fourth conductive traces and along the lengths of the third and fourth conductive traces; connecting each of the first and second conductive traces to a second connector for a second electrical component of the aircraft, grounding the second insulating film, and installing cabling along the surface to electrically connect the first conductive trace to the third conductive trace, and to connect the second conductive trace to the fourth conductive trace.

### SUMMARY OF THE DRAWINGS

For a better understanding the above explanation and for the sole purpose of providing an example, some non-limiting drawings are included that schematically depict a practical embodiment.

FIGS. 1A and 1B show inside surfaces of an aircraft door to illustrate a conventional harness system mounted to the surfaces.

FIG. 2 shows a block diagram for a conventional cable installation process.

FIG. 3 shows a first block diagram for printed cable installation on a harness system according to the present disclosure using aerosol jet as printing technology.

FIG. 4 shows a second block diagram for printed cable installation on a harness system according to the present disclosure using cold spray as printing technology.

FIG. 5 shows a printed cable installation and associated steps for the printing of the printed cable.

### DETAILED DESCRIPTION OF THE INVENTION

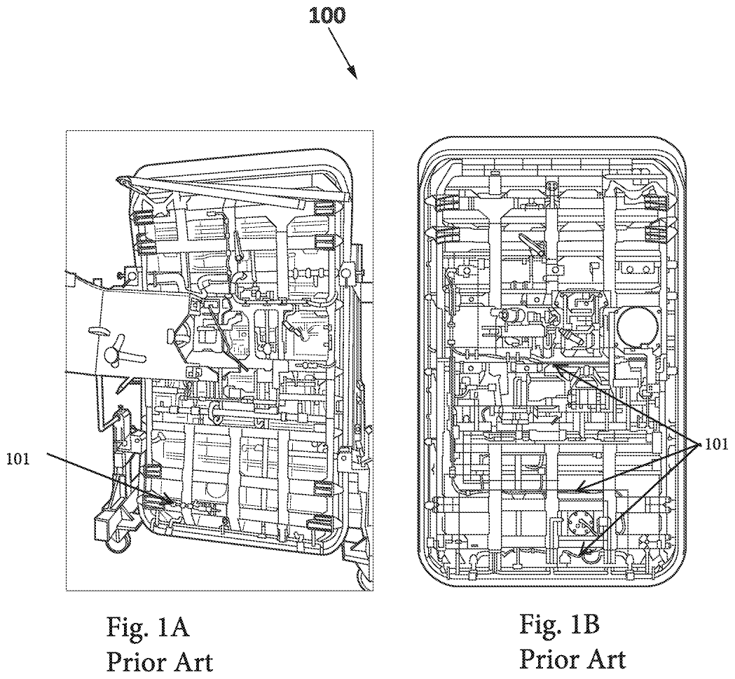

FIGS. 1A and 1B show a conventional harness system 100 for a door of an aircraft. FIG. 1A shows the inside surfaces of a front (exterior) portion of an aircraft door and FIG. 1B shows the inside surfaces of a back (interior) portion of the aircraft door. The front portion in FIG. 1A is mounted on a support frame with roller wheels.

Electrical cables 101 of a cabling harness system are mounted to various internal components and internal surfaces of the aircraft door. As previously mentioned, in some aircrafts a harness system can comprises 24 cables fulfilling bonding, grounding, power and analogue functions that have to be assembled on the door of the aircraft. This assembly is complex, costly and subjected to maintenance and aging.

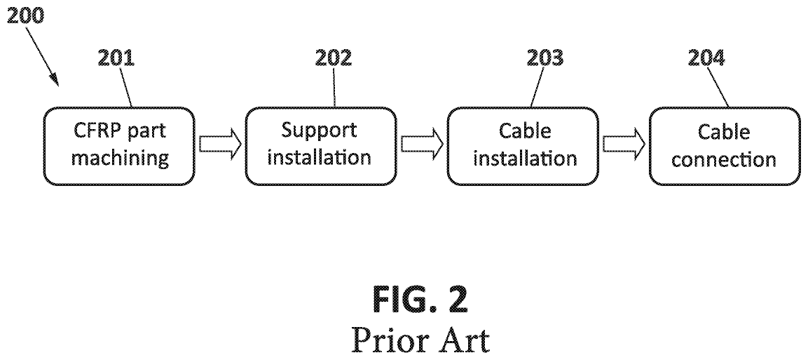

FIG. 2 shows a block diagram 200 for a conventional cable installation process. The block diagram 200 comprises block 201 for machining the CFRP surface so that said CFRP surface is cut into a desired final shape and size by a controlled material-removal process. The block diagram 200 comprises block 202 for support installation that can involve several steps as drilling/screwing and/or adhesion techniques involving a costly procedure with need of accurate process control in order to avoid compromising the system quality and performance. Furthermore, the block diagram 200 comprises block 203 for cable installation and block 204 for cable connection.

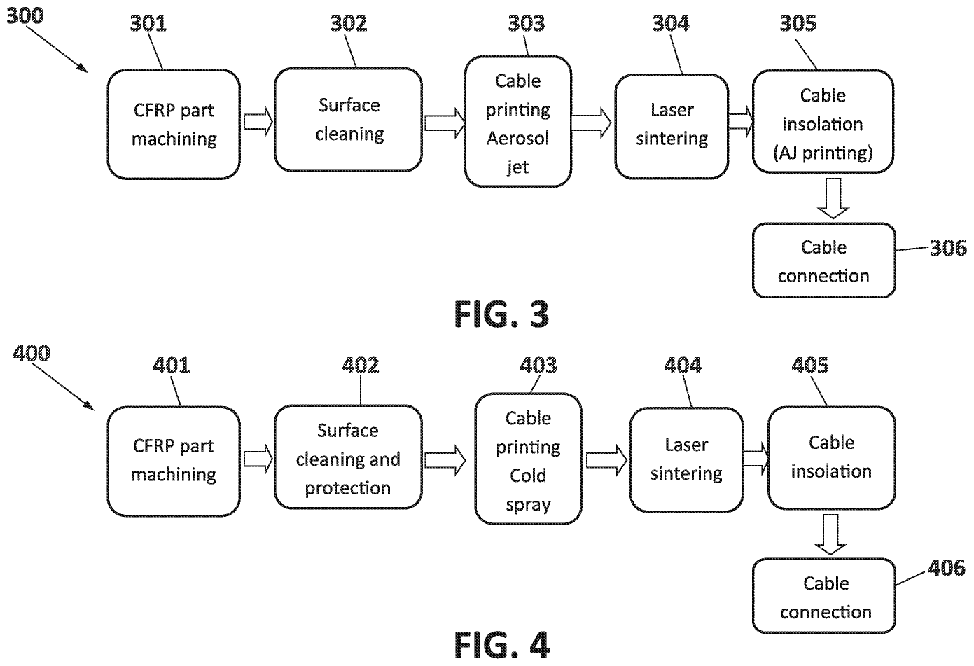

FIG. 3 shows a block diagram 300 for printed cable installation in a harness system for a CFRP surface of a fuselage of an aircraft. The conductive traces are printed using aerosol jet as printing technology. The block diagram 300 comprises block 301 for machining the CFRP surface so that said CFRP surface is cut into a desired final shape and size by a controlled material-removal process. The block diagram 300 further comprises block 302 for cleaning the CFRP surface. The block diagram 300 further comprises block 303 for printing pairs of metallic paths on the CFRP surface by using aerosol jet(s) of a powdered conductive material which are printed on the CFRP surface to form each of path in the pair of metallic paths.

The block diagram 300 further comprises block 304 for laser sintering to sinter the powder material comprised in the metallic paths. Sintering is the process of compacting and forming a solid mass of conductive material from the conductive powder comprised in the metallic printed paths. Sintering can be performed by applying heat with a laser without melting it to the point of liquefaction.

The block diagram 300 further comprises block 305 for cable isolation between pairs of metallic printed paths. In order to achieve the correct electrical conductivity, and consequently, a minimum electrical linear resistance and eliminate crosstalk, an insulating film between pairs of metallic paths is interposed. The insulating film provides shielding and protection between the pairs of metallic paths.

The block diagram 300 further comprises block 306 for completing the electrical circuit after applying a predetermined number of pairs of metallic paths as part of the harness system by connecting a voltage source, a load, etc. In an example, the harness system is built for a door of an aircraft that comprises 192 metallic printed paths grouped in 96 pairs corresponding to 24 twisted cables.

FIG. 4 shows a block diagram 400 for printed cable installation in a harness system for a CFRP surface of a fuselage of an aircraft. The metallic paths are printed using cold spray as printing technology. The block diagram 400 comprises block 401 for machining the CFRP surface.

The block diagram 400 further comprises block 402 for cleaning and protecting the CFRP surface. The block diagram 400 further comprises block 403 for mapping paths on the surface for conductive paths, and printing pairs of metallic traces on the CFRP surface along the paths by using a cold spray printing technology to print powered metal conductive material to form each of the conductive traces. Each path may have a length of less than five (5) meters. For example, a path may have a length of 0.5 to 2 meters.

The block diagram 400 further comprises block 404 for laser sintering to sinter the powder material comprised in the metallic paths. The block diagram 400 further comprises block 405 for cable isolation between pairs of metallic printed paths to achieve the electrical benefits of the twisted pair cable and obtain a minimum electrical linear resistance. The block diagram 400 further comprises block 406 for completing the electrical circuit after applying a predetermined number of pairs of conductive metallic paths required for the harness system.

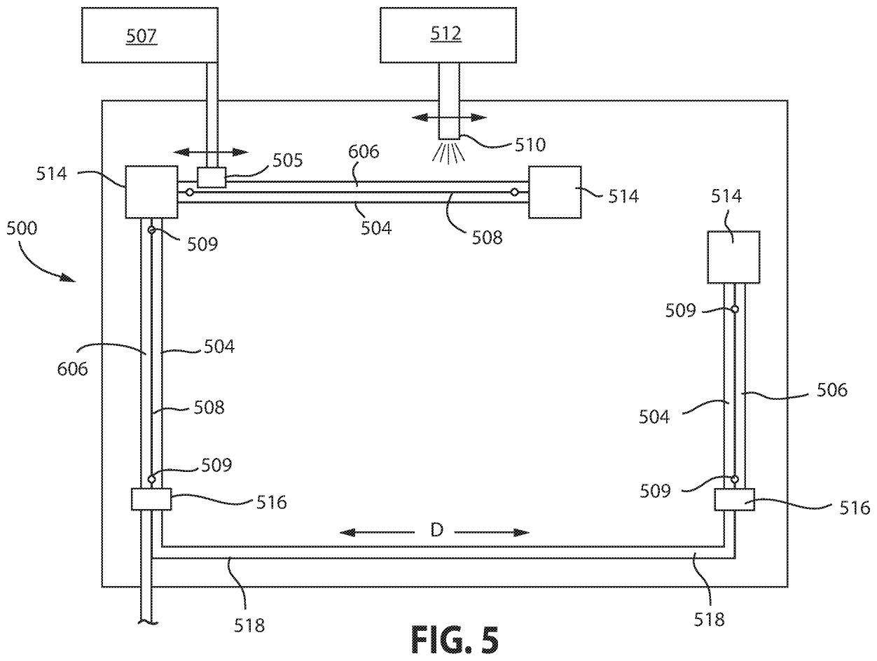

FIG. 5 illustrates an exemplary printed cable installation 500 on a surface 502 of a carbon fiber reinforced polymer composite (CFRP) panel in an aircraft. The surface 502 may be an interior surface of an aircraft door, an interior surface of an aircraft fuselage, an interior surface in an aircraft wing or other surface of a component for an aircraft.

Onto the surface 502, has been printed a pair of conductive traces 504, 506 that are separated by an insulating layer or strip 508 which is grounded, such as at both ends 509 of the insulating layer or strip. The insulating layer or strip 508 may form a ground trace that separates the conductive trances and may surrounds or partially surround the conductive traces. The insulating layer or strip 508 prevents electrical cross-talk between the conductive traces.

The conductive traces 504, 506 are printed with an additive printer 507 controlled by a computer programmed to automate the printing of the conductive traces. The computer controls the printer to move along the surface to print the conductive traces and the insulating layer or strip along predetermined paths. The conductive traces are sintered by a laser 510 after being printed on the surface 502. The laser may be computer controlled such that the laser moves (see double arrows) automatically over the conductive traces and optionally the insulating layer or strip.

The traces may be parallel or overlapping, and separated only by the insulating layer 508 or by a narrow gap having a width of, for example, 1 to 10 millimeters. The insulating strip 508 is in the narrow gap. The traces 504, 506 are each conductively coupled to respective electrical components 510 or wiring connectors 512 that connect to wire cables 518.

If the surface 502 has a length greater than five (5) meters, such as an interior surface of a fuselage, then distances (D) of greater than five meters may be traversed with a conductive cable 518 rather than printed conductive traces. The conductive cables 518 may include separate wires each of which are electrically connectable to one of the printed traces 504, 506 via a connector 516. The conductive cable 518 may also be used to provide a conductive path external to the surface 502. Thus, the printed traces 504, 506 may be used where the conductor distance is less than five meters, and wire cables 518 where the distance is greater than five meters.

Even though reference has been made to a specific embodiment of the invention, it is obvious for a person skilled in the art that the lightning protector described herein is susceptible to numerous variations and modifications, and that all the details mentioned can be substituted for other technically equivalent ones without departing from the scope of protection defined by the attached claims.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

The invention is:

1. A method for printing conductive traces for a cable installation in a harness system of an aircraft, the method comprising:
printing at least a first conductive trace comprising conductive particles onto a surface of an aircraft;
printing at least second conductive trace comprising conductive particles to the surface of an aircraft,
sintering the first and the second conductive traces by a laser; and
interposing an insulating film between the first and the second conductive traces.

2. The method of claim 1, wherein the first and second conductive traces each have a length of less than five (5) meters.

3. The method of claim 1, further comprising cleaning the surface of an aircraft before printing the first and second conductive traces.

4. The method of claim 3, further comprising protecting the surface of an aircraft before printing the first and second conductive traces.

5. The method of claim 1, wherein the printing technology comprises an additive ink-based printer.

6. The method of claim 5, wherein the additive ink-based printer is configured to project an aerosol jet of the conductive particles to form the first and second conductive traces.

7. The method of claim 5, wherein the additive printer includes an additive powder-based printer.

8. The method of claim 7, wherein the additive powder-based printer includes gas dynamic cold spray printer configured to spay a metallic power to form the first and second conductive traces.

9. The method according to claim 1, wherein the conductive particles include copper conductive particles.

10. A composite element for an aircraft with an integrated harness system comprising a plurality of pairs of conductive traces applied on a surface of the composite element with a printing technology, wherein each pair of conductive traces comprises:
a first and a second conductive traces; and
an insulated film interposed between the first and the second conductive traces,
wherein for the first and second trace have a length less than five (5) meters, and
wherein the plurality of pairs of conductive traces complete an electrical circuit of an aircraft harness system.

11. The composite element of claim 10, wherein the printing technology comprises ink-based printing.

12. The composite element of claim 10, wherein the printing technology comprises powder-based printing.

13. The composite element of claim 12, wherein the composite element is a part of a fuselage section.

14. The composite element of claim 10, wherein the composite element is a door of the aircraft.

15. A method to install conductive elements on a component for an aircraft, the method comprising:
identifying a surface of the component suitable for receiving printed conductive material, wherein the surface of a Carbon Fiber Reinforced Polymer Frame (CFRP);
mapping a first path for conductive traces, wherein the first path is less than five (5) meters and at least 0.5 meters;
printing first and second conductive traces along the first path, wherein the printing includes printing conductive particles onto the surface along the first path, wherein a gap between the first and second conductive traces is no greater than 10 millimeters along the lengths of the conductive traces;
sintering the first and the second conductive traces by heating the first and second conductive traces with a laser;
placing a first insulating film or trace between the first and the second conductive traces and along the lengths of the first and second conductive traces;
connecting each of the first and second conductive traces to a first connector for a first electrical component of the aircraft, and
grounding the first insulating film or trace.

16. The method of claim 15, wherein the component is an aircraft door and the surface is an interior surface of a door of the aircraft.

17. The method of claim 15 further comprising:
mapping a second path for conductive traces, wherein the second path is less than five (5) meters and at least 0.5 meters, wherein the second path is separated by at least five (5) meters from the first path;
printing third and fourth conductive traces along the second path, wherein the printing includes printing conductive particles onto the surface along the first path, wherein a gap between the first and second conductive traces is no greater than 10 millimeters along the lengths of the conductive traces;
sintering the third and the fourth conductive traces by heating the third and fourth conductive traces with the laser;
placing a second insulating film or trace between the third and the fourth conductive traces and along the lengths of the third and fourth conductive traces;
connecting each of the first and second conductive traces to a second connector for a second electrical component of the aircraft,
grounding the second insulating film, and
installing cabling along the surface to electrically connect the first conductive trace to the third conductive trace, and to connect the second conductive trace to the fourth conductive trace.

18. The method of claim 16, wherein the component is a fuselage of the aircraft and the surface is an interior surface of the fuselage.
